(19) United States
(12) Patent Application Publication
(10) Pub. No.: US 2006/0207790 A1
(43) Pub. Date: Sep. 21, 2006

(54) Bonding pads having slotted metal pad and meshed via pattern

(76) Inventor: Jayoung Choi, Sungnam-si (KR)

Correspondence Address: HARNESS, DICKEY & PIERCE, P.L.C., P.O. BOX 8910, RESTON, VA, 20195, US

(21) Appl. No.: 11/327,327

(22) Filed: Jan. 9, 2006

(30) Foreign Application Priority Data
Mar. 15, 2005 (KR) 10-2005-0021473

(51) Int. Cl. H05K 1/11

(52) U.S. Cl. 174/262; 174/255

(57) ABSTRACT

Bonding pad structures according to the invention will include one or more dielectric layer patterns and/or conductive via patterns provided within the periphery of an associated primary conductive layer pattern. These patterns may be configured so that the patterns on successive levels of the bonding pad metallization sequence are offset in a manner that will tend to increase the resistance of the resulting bonding pad structure to subsequent mechanical and/or thermal stresses. By improving adhesion of the bonding pad structures, reductions may also be achieved in the frequency and severity of separation, delamination or peeling of the various conductive and dielectric layers incorporated into the bonding pad structure.

### PRIORITY STATEMENT

This U.S. non-provisional application claims benefit of priority under 35 U.S.C. § 119 from Korean Patent Application No. 2005-21473, which was filed on Mar. 15, 2005, the entire contents of which are incorporated herein by reference.

### BACKGROUND OF THE INVENTION

1. Field of the Invention

This invention relates to the configuration and manufacture of certain structures for semiconductor devices, and more particularly, to the configuration and manufacture of certain multi-layer conductive structures including, for example, bonding pads.

1. Description of Related Art

During the fabrication of integrated circuits, bonding pads are commonly utilized for providing electrical connections between internal circuitry of the integrated circuit and an external circuit. By the formed bonding pads and the metal plugs formed in dielectric layers, the external circuit can make electrical connection with the internal circuit of the integrated circuit.

A conventional bonding pad structure is illustrated in FIG. 1 which shows a cross-sectional view of a conventional bonding pad structure comprising a plurality of metal pads 2a-2d, a plurality of interlayer dielectrics 3a-3d provided between the metal pads and a plurality of independent contact plugs 4a-4c which are utilized for establishing electrical connections between adjacent metal pads through the intervening interlayer dielectric.

The conventional bonding pad structures as illustrated in FIG. 1 are susceptible to certain limitations and problems including, for example, material segregation and/or cracking at or along the interface between a conductive wire and a metal pad and/or between a metal pad and an adjacent interlayer dielectric as the result of mechanical and/or thermal stress. The processes for producing such structures can also have certain limitations and problems including, for example, dishing, i.e., the excessive removal of material from the central expanse of a “softer” material surrounded by harder material, such as metal surrounded by a dielectric, that produces a concave surface region and causes undesirable thinning of the material.

Various structures have been proposed for altering the structure of the bonding pads to address these deficiencies including, for example, forming bonding pads having first metal layer and second metal layer separated by a dielectric layer through which a plurality of conductive plugs are formed. Another proposal would utilize a bonding pad structure having a capping layer disposed over a first supporting layer that may be configured as a solid or slotted sheet which, in turn, may be disposed over a second supporting layer that may be configured with voids in a slotted or checkerboard arrangement. Variations of this proposal provide for a bonding pad structure in which the first and second supporting layers are provided with a plurality of slots arranged perpendicularly to the slots in the other supporting layer but neither parallel nor normal with respect to the major edges of the overall structure.

### SUMMARY OF THE INVENTION

The bonding pad structures configured according to the invention may increase the resistance of the resulting bonding pad structure to the mechanical and/or thermal stresses to which it will be subjected during the remaining portions of the fabrication and assembly processes, as well as those to which the final semiconductor device may be subjected during subsequent use.

The bonding pad structures configured according to the invention may increase the resistance of the resulting bonding pad structure to separation, delamination or peeling of the various conductive and dielectric layers incorporated into the bonding pad structure.

The bonding pad structures configured according to the invention may improve the manufacturability of the bonding pad structure including, for example, reducing susceptibility to dishing and/or permitting the use of a wider range of conductive and dielectric materials in the fabrication of the bonding pad structure that may allow for improved performance and/or reliability.

Bonding pad structures according to a first embodiment of the invention will include a first dielectric layer; a first conductive pad pattern formed in the first dielectric layer and surrounding an elongated portion of the first dielectric layer; a second dielectric layer formed on the first conductive pad pattern; a first plurality of conductive vias having a first configuration formed through the second dielectric layer and in electrical contact with the first conductive pad pattern; a second conductive pad pattern formed in the second dielectric layer in electrical contact with the first plurality of conductive vias and surrounding an elongated portion of the second dielectric layer; a third dielectric layer formed on the second conductive pad pattern; a second plurality of conductive vias having the first configuration formed through the third dielectric layer and in electrical contact with the second conductive pad pattern; and a third conductive pad pattern formed in the third dielectric layer and in electrical contact with the second plurality of conductive vias.

Bonding pad structures according to the first embodiment of the invention may be further modified by, for example, configuring the first conductive pad pattern to surround a plurality of elongated portions of the first dielectric layer and/or configuring the second conductive pad pattern to surround a plurality of elongated portions of the second dielectric layer. Additional modifications of the bonding pad structures according to the first embodiment may include configuring the elongated portion of the first dielectric layer to have an open configuration, e.g., not completely surrounded by the conductive pad pattern, and/or configuring the elongated portion of the second dielectric layer to have an open configuration. Similarly, the elongated portion of the first dielectric layer may be configured to have a closed configuration, e.g., completely surrounded by the conductive pad pattern and/or enclosing a portion of the conductive pad pattern, and/or configuring the elongated portion of the second dielectric layer to have a closed configuration.

Bonding pad structures according to the first embodiment of the invention may be further modified by, for example, configuring the elongated portion(s) of the first dielectric layer to comprise no more than 10% of an area defined by the periphery of the first conductive pad structure and/or configuring the elongated portion of the second dielectric layer represents no more than 10% of an area defined by the periphery of the second conductive pad structure.

As will be appreciated by those skilled in the art, the associated patterns may be configured to provide substantially any desired ratio between the surface area of the conductive pad structures and the associated elongated portions of the dielectric layers whereby the dielectric layer area may comprise, for example, 15%, 20%, 25%, or perhaps as much as 50%, of the total area. As will also be appreciated by those skilled in the art, as the relative area of the dielectric layer decreases, the advantages provided by the dielectric portions will tend to be reduced, increasing the likelihood of damage during the fabrication of the bonding pad structure at process steps such as, for example, CMP. This reduction may be addressed to some degree by modifying the configuration of the dielectric portions that remain to improve their effectiveness. As will further be appreciated by those skilled in the art, increasing the relative area of the dielectric portions can increase the resistance of the overall structure and provide less area for the formation of via connections between adjacent conductive pad patterns.

Bonding pad structures according to the first embodiment of the invention may be further modified by, for example, arranging the elongated portion(s) of the first and second dielectric layers in complementary patterns including, for example, arranging the elongated portions of the first and second elongated dielectric portions whereby a longitudinal axis associated with the first elongated dielectric portion and a longitudinal axis associated with the second elongated dielectric portion define a rotational, axial, lateral and/or radial offset between the two sets of dielectric portions. For example, a rotational offset θ of 90 degrees, e.g., a substantially perpendicular arrangement, between similarly configured first and second elongated dielectric portions will tend to reduce the vertical overlap between successive patterns, thereby improving the strength of the resulting structure.

As used herein, the term rotational offset refers to a situation in which one pattern is rotated about an axis relative to another pattern although the moved pattern and the reference pattern may or may not be arranged in a generally coaxial relationship. As used herein, the term axial and lateral offsets refer to the shifting of the moved pattern along a single axis relative to the reference pattern without changing the size, e.g., the absolute x and y dimensions, or aspect ratio, e.g., the ratio of the x and y dimensions, of the moved pattern. As used herein, the term radial offset refers, particularly with regard to patterns that are symmetric about a central point, to shifting relative portions of the moved pattern along radial lines, thereby tending to change the size of the moved pattern without changing the aspect ratio of the moved pattern.

The bonding pad structure according to the first embodiment of the invention may include an elongated portion of the first dielectric layer arranged in a substantially parallel and laterally offset orientation relative to the elongated portion of the second dielectric layer. This offset arrangement between sequential series of patterns used for fabricating the bonding pad structures may be extended to a first plurality of conductive vias arranged to establish an offset orientation relative to the second plurality of conductive vias. As will be appreciated by those skilled in the art, the associated patterns may be configured to provide substantially any desired degree of vertical overlap between sequential series of conductive vias to provide, for example, no more than about 90% vertical overlap between successive via patterns. As will also be appreciated by those skilled in the art, this degree of vertical overlap may be modified as desired by adjusting the relative pattern layers accordingly to provide, for example, degrees of vertical overlap of no more than 75%, 50%, 25%, 10%, below 10% or even no vertical overlap, between the conductive via surface areas of successive conductive via patterns.

The bonding pad structure according to the first embodiment of the invention may also include elongated portion(s) of the first and/or second dielectric layers arranged in a substantially parallel and laterally offset orientation relative to the preceding and/or following conductive via patterns whereby the via patterns are arranged only in regions between adjacent ones of the elongated portions of the dielectric layers, e.g., an arrangement that results in little or no vertical overlap between the via patterns and the dielectric patterns. The dielectric patterns and/or the via patterns may also be arranged to produce a “mesh” or “basket” pattern when viewed from above with sequential patterns of similar or dissimilar materials are rotationally offset by, for example, 90 degrees and/or axially offset, typically along only the x or y axis, to form a pattern with relatively small regions in which there is vertical overlap between the successive patterns as illustrated, for example, in FIG. 6A or in an overlay of FIG. 2A and FIG. 3.

Another embodiment of the bonding pad structure according to the invention includes a first dielectric layer; a first conductive pad pattern formed in the first dielectric layer and surrounding an elongated portion of the first dielectric layer; a second dielectric layer formed on the first conductive pad pattern; a first plurality of conductive vias having a first configuration formed through the second dielectric layer and in electrical contact with the first conductive pad pattern; a second conductive pad pattern formed in the second dielectric layer in electrical contact with the first plurality of conductive vias; and a passivation pattern formed on and exposing the majority of an upper surface of the second conductive pad pattern.

As with the first embodiment of a bonding pad structure according to the invention, this embodiment may also be modified by, for example, configuring the first conductive pad pattern to surround a plurality of elongated portions of the first dielectric layer. The conductive pad pattern may also be configured to produce one or more “open” and/or closed configurations in the dielectric layer. This embodiment of a bonding pad structure may also incorporate one or more of the structural adaptations disclosed above with respect to the first embodiment of a bonding pad structure according to the invention.

The invention also encompasses embodiments of wafer fabrication processes that incorporate the steps necessary to form bonding pad structures according to the invention. A first embodiment of a method of forming a bonding pad structure according to the invention includes the steps of forming a first dielectric layer; removing portions of the first dielectric layer to form a first recessed conductive pad region surrounding an elongated portion of the first dielectric layer; depositing a first conductive material layer; removing an upper portion of the first conductive material layer to form a first conductive pad surrounding the elongated portion of the first dielectric layer; forming a second dielectric layer; removing first portions of the second dielectric layer to form a first plurality of via openings having a first configuration; removing a second portion of the second dielectric layer to form a second recessed conductive pad region surrounding an elongated portion of the second dielectric layer; depositing a second conductive material layer; removing an upper portion of the second conductive material layer to form a second conductive pad surrounding the elongated portion of the second dielectric layer and a first plurality of conductive vias establishing electrical contact between the first and second conductive pads; forming a third dielectric layer; removing first portions of the third dielectric layer to form a second plurality of via openings; removing a second portion of the third dielectric layer to form a third recessed conductive pad region; depositing a third conductive material layer; and removing an upper portion of the third conductive material layer to form a third conductive pad and a second plurality of conductive vias establishing electrical contact between the second and third conductive pads.

As will be appreciated, the embodiment of a method according to the invention as described above may be modified by, for example, arranging the second plurality of conductive vias arranged in the first configuration and offsetting the second conductive vias in rotational, radial and/or lateral directions from the first plurality of conductive vias in order to reduce vertical overlap between the first and second conductive via patterns. As described above with respect to the embodiments of the bonding pad structures according to the invention may be formed so that the elongated portion of a first dielectric layer will be rotationally offset from the elongated portion of a second or successive dielectric layer or other reference layer.

### BRIEF DESCRIPTION OF THE DRAWINGS

The invention will become more apparent by describing in detail exemplary embodiments thereof with reference to the attached drawings in which:

FIG. 1 provides a cross-sectional view of a conventional bonding pad construction used for manufacturing semiconductor devices;

FIG. 2A is top plan view of an N metal pad and an N via pattern for a bonding pad according to an example embodiment of the invention and FIG. 2B is an enlarged view of the via pattern portion 140 of FIG. 2A;

FIG. 3 is top plan view of an N+1 metal pad and an N+1 via pattern for a bonding pad according to an example embodiment of the invention;

FIG. 4 is cross-sectional view along line A-A′ of an example embodiment of a bonding pad structure according to an embodiment of the invention that incorporates both the N and N+1 metal pads and N and N+1 via patterns illustrated in FIGS. 2 and 3 respectively;

FIGS. 5A and 5B illustrate plan views of example embodiments of N and N+1 metal pads, each having a plurality of slots arranged to be substantially perpendicular to the orientation of the slots on the adjacent metal pad;

FIG. 6A illustrates a plan view of an example embodiment for the offset alignment of adjacent via arrays 140, 240 wherein the arrays are offset from each other along a generally horizontal axis resulting in formation of both singular and overlapped regions 190 (with cross-hatching);

FIG. 6B illustrates a plan view of an example embodiment for the offset alignment of adjacent via arrays 140, 240 wherein the arrays are offset from each other along a generally diagonal axis resulting in formation of both singular and overlapped regions 190 (with cross-hatching);

FIGS. 7A-7C illustrate alternative example embodiments for the via patterns utilized for establishing contact between sequential metal pads or other conductive materials;

FIG. 8 is a cross-sectional view of an example embodiment of a bonding pad structure according to the invention;

FIG. 9 is a cross-sectional view of a final or upper metal pad in combination with a wide type via pattern according to an example embodiment of a bonding pad structure according to the invention;

FIG. 10 is a cross-sectional view of an example embodiment of a bonding pad structure according to the invention;

FIG. 11 is a plan view of an example embodiment of a bonding pad structure according to the invention with a more complex slot structure and offset via arrays;

FIG. 12 is a plan view of another example embodiment of a bonding pad structure according to the invention with a more complex slot structure and offset via arrays;

FIGS. 13A-13D are plan views of various example embodiments of conductive pattern layers of respective bonding pad structures according to the invention with having various open and closed slot structures; and

FIGS. 14A-14D are plan views of various example embodiments of two layer stacks of respective conductive pattern layers illustrated in FIGS. 13A-13D in which the two layers are rotationally offset to define various vertical overlaps between the openings provided in the conductive patterns.

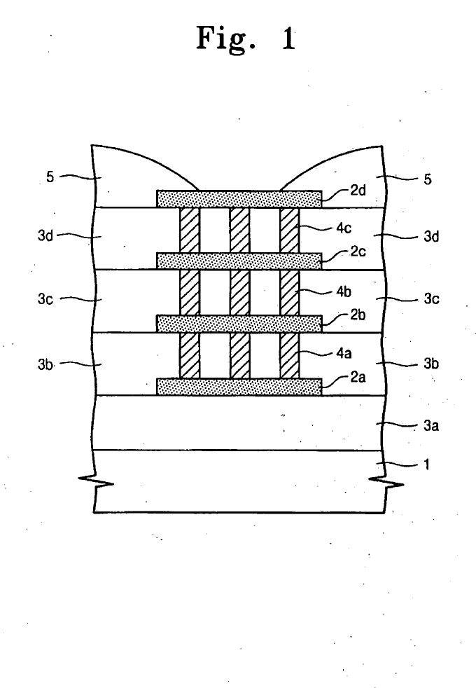

These drawings have been provided to assist in the understanding of the exemplary embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity.

Those of ordinary skill in the art will also appreciate that a range of alternative configurations have been omitted simply to improve the clarity and reduce the number of drawings. Those of ordinary skill will appreciate that certain of the various process steps illustrated or described with respect to the exemplary embodiments may be selectively and independently combined to create other methods useful for manufacturing semiconductor devices without departing from the scope and spirit of this disclosure.

### DETAILED DESCRIPTION OF EXAMPLE EMBODIMENTS

The present invention provides a range of bonding pad structures that incorporate via patterns and slotted metal pads and methods of fabricating such structures for addressing the deficiencies of the conventional bonding pad constructions.

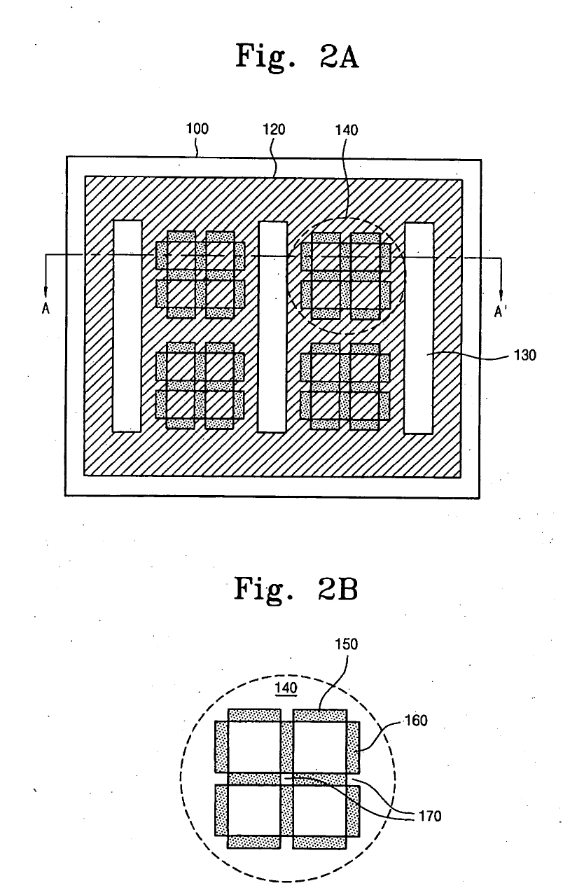

As illustrated in FIG. 2A, a metal pad 120 is formed on a substrate 100. The metal pad includes at least one slot 130, e.g., an elongated opening formed at least partially through the metal layer from which the metal pad is formed, and a first interlayer dielectric is formed over the first (or N^{th}) metal pad. Although as illustrated the opening formed in the metal pad 120 is an elongated slot 130, those skilled in the art will appreciate that the opening may be readily adapted to provide a wide range of configurations of dielectric regions exposed within the periphery of the metal pad.

As used herein, N and N^{th} are to be considered interchangeable variables which refer to a level or a structure arranged below, i.e., formed earlier in the device fabrication process, a corresponding N+1 or N+1^{th} level or structure. For example, if the N^{th} level is the second level, then the N+1^{th} level is the third level. As will be appreciated, the number of levels above or below a reference level N may be easily indicated through the use of appropriate positive values (for layers above the N^{th} layer) and negative values (for layers below the N^{th} layer).

As will also be appreciated each conductive “level” formed in the bonding pad structure according to the invention will be separated from at least one adjacent conductive level by a corresponding dielectric layer through which are provided conductive vias to establish an electrical connection between adjacent conductive levels. The number, size and material used in the conductive vias will determine both the contribution of the conductive vias to the overall resistance (Ω) and the overall current carrying capability of the entire bonding pad structure. Similarly, the thickness, material and size of the larger metal pads will also contribute to the overall resistance of the bonding pad structures according to the invention.

A series of first via openings 140 is then formed through the interlayer dielectric to expose portions of the surface of the metal pad 120. These first via openings are then filled with one or more conductive materials, including, for example, one or more conductive materials selected from a group consisting of aluminum, copper and their alloys, other metals such as titanium, tantalum and tungsten and nitrides thereof to form an electrical connection to the first metal pad. The dielectric and conductive materials may be subjected to one or more processes such as etch and/or chemical mechanical polishing (CMP) to form a relatively smooth, planar surface suitable for additional processing.

Depending on the particular process being utilized for fabricating the semiconductor devices, a second metal layer may be deposited on the planarized surface to establish electrical connections to the upper surfaces of the conductive material(s) provided in the first via openings. This layer may then be patterned and etched using, for example, conventional photolithography and wet and/or dry etch processes to form a second metal pad that also may include at least one slot 230 extending through the second metal pad.

Alternatively, a damascene process may be utilized in which another dielectric layer may be deposited and then patterned and etched to open designated regions, including those above the conductive materials provided in the first via openings. A second metal layer may then be deposited in the open regions and on the remaining portions of the dielectric layer and then processed using, for example, CMP, to remove those portions of the metal layer that are not within the defined opening, e.g., those above the slot and those on the unetched portions of the dielectric layer, thereby forming a second metal pad 220.

Both the first and second metal layers can be formed from a single metal or metal alloy, but one or more of the metal layers may incorporate layers of refractory metals, silicides or conductive nitrides for providing one or more barrier layers. Similarly, depending on the configuration of the relevant elements and the current and voltage demands of the particular semiconductor device, one or more metal layers may be replaced by or provided in conjunction with a conductive material, such as, for example, TaN, TiN and WN that would increase resistance during subsequent high temperature operations. In most instances, however, it is believed that aluminum, aluminum alloys, copper and/or copper alloys will be sufficient for at least the highest conductive layer levels. With copper and copper alloys, however, the use of a barrier layer, for example a combination metal/metal nitride barrier layer, such as Ta/TaN, will generally be preferred.

Both the slot(s) 230 provided in the second metal and the particular pattern of via openings 240 formed in the dielectric layer overlaying the second (N+1^{th}) metal pad may be offset in some fashion, for example, shifted along an axis or provided as a mirror or complementary structure to the slot(s) 130 and via openings 140 provided in connection with the first metal pad. Those of ordinary skill in the art will appreciate that, depending on the relative configurations of the structures associated with the first and second metal pads, a wide range of structures, including those with some degree of overlap, may be utilized for practicing this invention.

In any event, once the second (or N+1^{th}) metal pad 220 has been formed, another interlayer dielectric is formed over the second metal pad 220. A series of second via openings 240 are a formed through the interlayer dielectric to expose portions of the surface of the metal pad 220. These second via openings are then filled with one or more conductive materials, including, for example, one or more conductive materials selected from a group consisting of aluminum, copper and alloys, other metals such as titanium, tantalum and tungsten and nitrides thereof to form an electrical connection to the second metal pad. The dielectric and conductive materials may be subjected to one or more processes such as etch and/or chemical mechanical polishing (CMP) to form a relatively smooth, planar surface suitable for additional processing.

Depending on the particular process being utilized for fabricating the semiconductor devices, a third metal layer may be deposited on the planarized surface to establish electrical connections to the upper surfaces of the conductive material(s) provided in the second via openings. This layer may then be patterned and etched using, for example, conventional photolithography and one or more wet and/or dry etch processes to form a second metal pad.

Alternatively, a damascene process may be utilized in which another dielectric layer may be deposited and then patterned and etched to open designated regions, including those above the conductive materials provided in the second via openings. As will be appreciated by those of ordinary skill in the art, the basic sequence of forming an insulating layer on a metal pad and opening vias through which electrical contact may be made to the underlying conductor may be repeated for layers N+2, N+3 etc., as desired by those practicing the invention.

One or more additional metal layers, including for example a third (or final) metal layer, may then be deposited in the open regions and on the remaining portions of the dielectric layer and then processed using, for example, CMP, to remove those portions of the metal layer that are not within the defined opening, thereby forming a third metal pad 350. If the third metal pad 350 is the final metal layer in the bonding pad structure, the periphery may by protected with a passivation layer of nitride or other suitable material that will tend to suppress or prevent contamination and/or mechanical damage to the bonding pad structure.

FIG. 2B illustrates an enlarged portion of the bonding pad structure illustrated in FIG. 2A, specifically one of the via arrays 140 provided across the surface of the first metal pad 120. As illustrated in FIG. 2B, the via array may include horizontal segments 150, vertical segments 160 and unopened regions 170 where the horizontal and vertical segments approach one another. As will be appreciated by those skilled in the art, the adjectives horizontal and vertical are used herein simply for convenience relevant to the orientation of FIG. 2B and do not necessarily have any correlation to the actual physical orientation of the referenced structure.

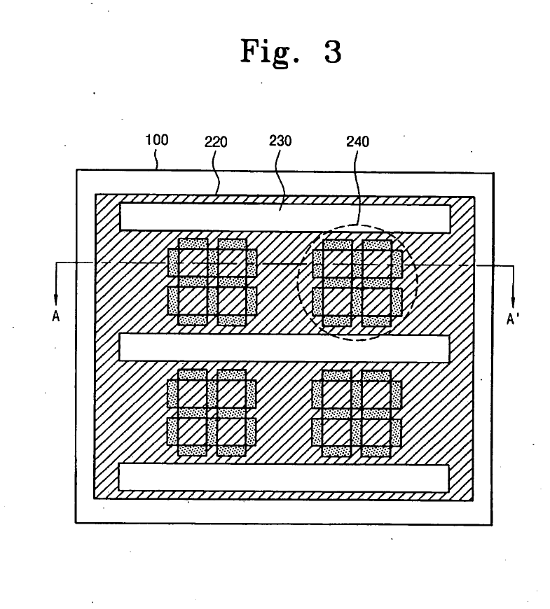

FIG. 3 illustrates a plan view of an N+1 metal pad and an N+1 via pattern that can be utilized in the fabrication of bonding pad structures in accordance with an example embodiment of the present invention. As illustrated in FIG. 3, the N+1 metal pad 220 includes a plurality of slots 230 extending at least partially through the metal pad and several pluralities of via arrays 240 arranged between the slots.

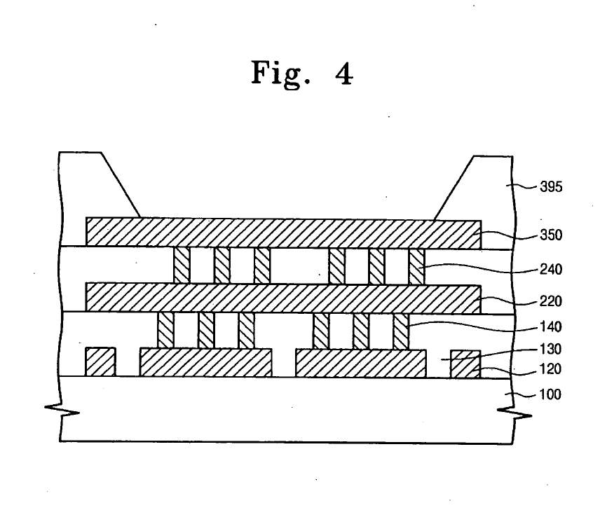

FIG. 4 illustrates a cross-sectional view of an example embodiment of a bonding pad structure according to the invention that incorporates the N and N+1 metal pads and via arrays illustrated in FIGS. 2A and 3. As shown in FIG. 4, the N^{th} metal pad 120 is formed on the substrate 100. Depending on the particular fabrication process being utilized, the “slots” 130 may represent residual portions of a dielectric material layer that was patterned and etched prior to deposition of the metal layer. The upper portions of the overlying metal layer may then be removed with an appropriate etch or CMP process to expose the surface of the dielectric material layer and define the metal pad with “slots” formed therein.

Alternatively, the metal layer may be deposited, patterned and etched to both define the periphery of the metal pad and open the “slots” 130 by removing portions of the metal from within the periphery of the metal pad 120. These openings or slots 130 will then be filled with a dielectric material during the subsequent deposition of the interlayer dielectric material.

Regardless of how the slots are formed, they establish regions of dielectric material, which are typically much harder than the surrounding metal, that will tend to reduce or eliminate “dishing” of the metal pad 120 during subsequent CMP processing. The excess dielectric material may then be removed with an appropriate CMP process to provide a substantially planarized surface suitable for subsequent processing.

An interlayer dielectric is then deposited or otherwise formed over the upper surface of the metal pad 120 and a number of vias 140, which may be arranged in a single pattern or one or more repeating patterns, are opened to expose portions of the surface of the underlying metal pad. These vias are then filled with one or more conductive materials, including, for example, one or more conductive materials selected from a group consisting of aluminum, copper and alloys, other metals such as titanium, tantalum and tungsten and nitrides thereof to form an electrical connection to the metal pad 120. When more than one conductive material is utilized, for example, thin layer of metal nitride, for example TaN, can be formed on the walls of the vias, followed by a layer of the metal, for example Ta, and, in some instances another layer of another conductive material such as Cu or Al. The dielectric and conductive materials may be subjected to one or more processes such as etch and/or CMP processing to form a relatively smooth, planar surface suitable for additional processing.

As shown in FIG. 4, the N+1^{th} metal pad 220 is formed on the upper surface of the interlayer dielectric formed over the N^{th} via arrays 140. Depending on the particular fabrication process being utilized, the slots 230 (not shown in FIG. 4), as with the slots 130 discussed above, may represent residual portions of the dielectric material layer that was patterned and etched prior to deposition of the metal layer or openings formed in the metal pad 220 and subsequently filled with a dielectric material during the subsequent deposition of the next interlayer dielectric material.

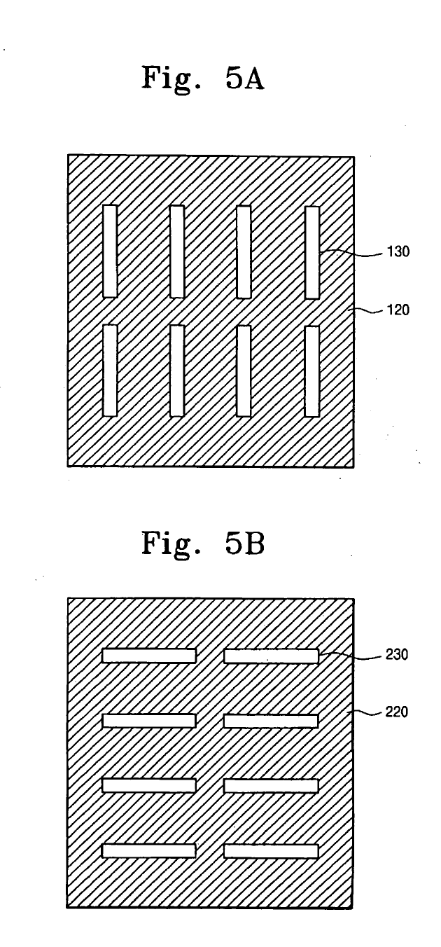

Additionally, the slots 130 and 230 may be arranged in corresponding or complementary patterns so as to reduce or eliminate those regions in which the two levels of slots are vertically “stacking.” By alternating the patterns of the slots 130, 230, as illustrated in FIGS. 5A and 5B, and as described below the via arrays 140, 240, the overall mechanical strength of the resulting bonding pad structure may be improved. Regardless of how the slots are formed, they establish regions of dielectric material that will tend to reduce or eliminate “dishing” of the metal pad 220 during subsequent CMP processing.

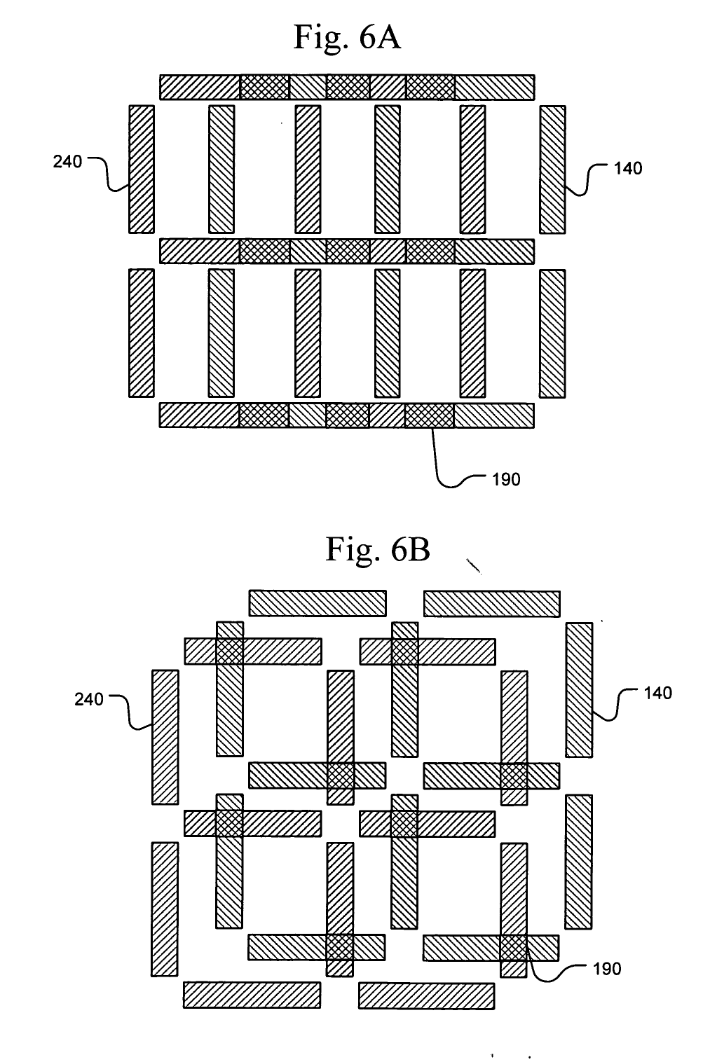

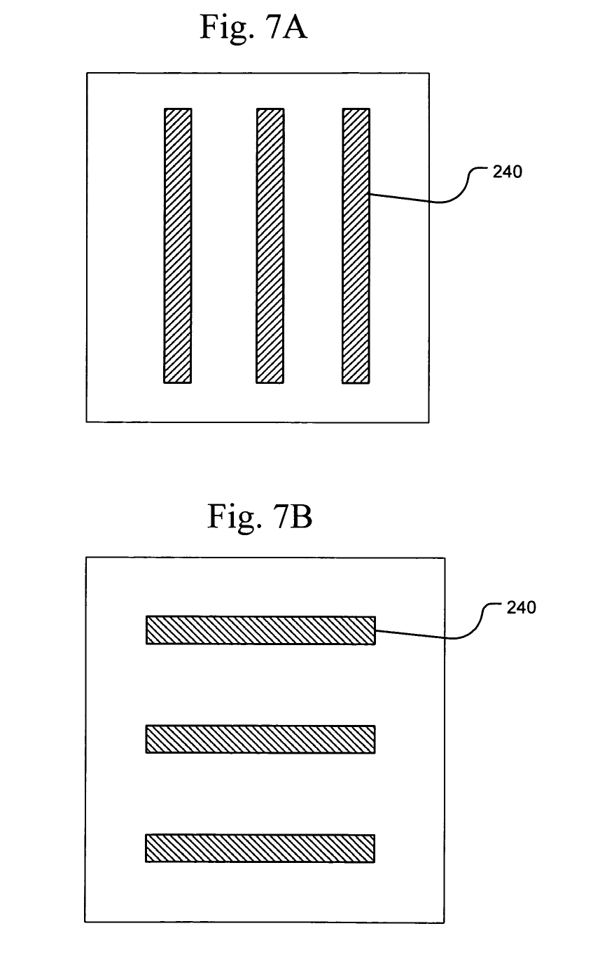

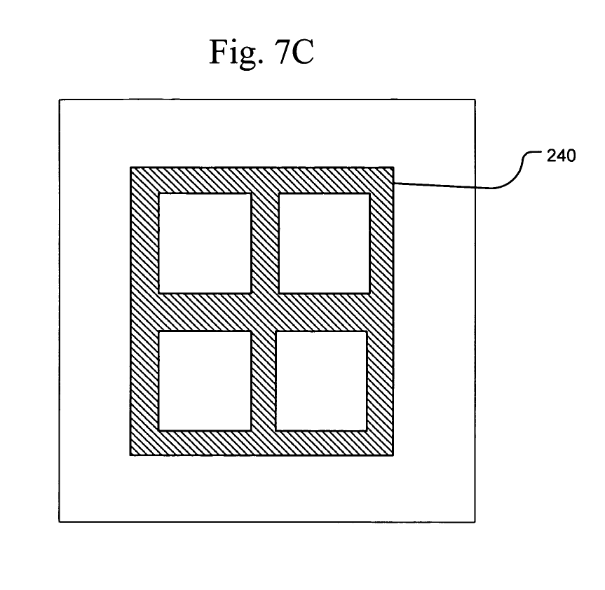

An interlayer dielectric is then deposited or otherwise formed over the upper surface of the metal pad 220 and a number of N+1^{th} vias 240, which may be arranged in a single pattern or one or more repeating patterns, are opened to expose portions of the surface of the underlying metal pad. The N+1^{th} vias 240 may be arranged in corresponding and/or complementary patterns, as illustrated in FIGS. 7A-7C, with the lower N^{th} vias 140 and the alternating or sequential levels of via arrays may be offset in radial and/or axial directions as illustrated in FIGS. 6A, 6B, 11 and 12. These vias 240 are then filled with one or more conductive materials, including, for example, one or more conductive materials selected from a group consisting of aluminum, copper and alloys, other metals such as titanium, tantalum and tungsten and nitrides thereof to form an electrical connection to the metal pad 220. The dielectric and conductive materials may be subjected to one or more processes such as etch and/or CMP processing to form a relatively smooth, planar surface suitable for additional processing.

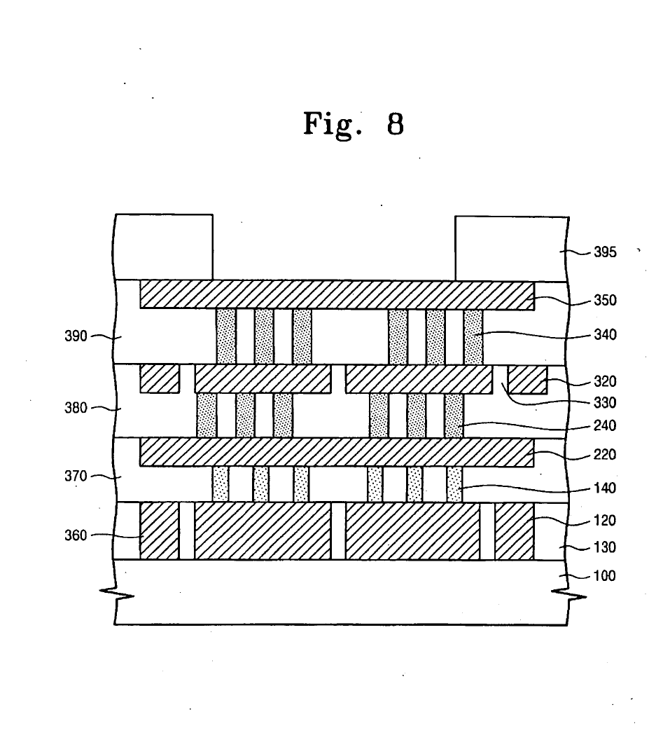

An N+2^{th} metal pad 350, in this instance a third pad, may then be formed on the N+1^{th} dielectric layer and via array(s) 240 to provide the outer contact surface for the bonding pad structure. A protective coating or passivation layer may be deposited, patterned and etched to form a protective material pattern 395 that extends over peripheral portions of the metal pad 350 to complete an exemplary bonding pad structure. Although this bonding pad structure has been described as having three separate metal pads, those skilled in the art will appreciate that, as illustrated in FIG. 8, additional metal pads 320, via arrays 340 and dielectric layers 390 may be utilized to produce alternative bonding pad structures.

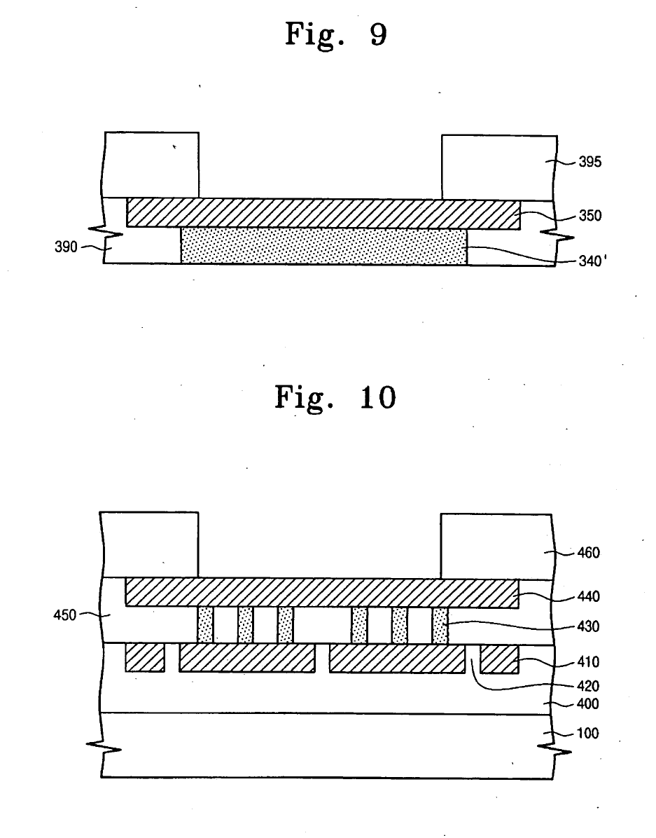

With respect to the structures used to establishing electrical contact between two adjacent metal pads, particularly between the exposed metal pad 350 and the next lower metal pad as illustrated in FIG. 9, the via arrays may be replaced with a single large conductor 340′. One advantage of this structure is reduced resistance between the exposed metal pad 350 and the underlying metal pad as compared to that achieved with via arrays and perhaps better suited for higher current connections such as fixed or rail voltage lines, e.g., V_{cc} and Vₛₛ, as opposed to signal lines.

As illustrated in FIG. 10, other embodiments of the invention may incorporate fewer layers. As illustrated in FIG. 10, an interlayer dielectric 400 may be formed on the substrate 100. An upper portion of the interlayer dielectric can then be patterned and etched to form recesses into which metal or another conductive material 410 can be deposited using, for example, a damascene process, in which a layer of conductive material is deposited and then the upper portion is removed to leave isolated regions of conductive material in the previously formed recesses. Of course, as described above, the conductive material may be patterned and then a second interlayer dielectric layer 450 can be deposited to separate the conductive material (not shown).

Once the lower or first conductive material pattern 410 has been formed, a second interlayer dielectric layer 450 can be deposited over the conductive pattern and the exposed surfaces of the extended portions of the first interlayer dielectric material 420 that fill the “slots” formed in the first conductive material pattern. The second interlayer dielectric layer 450 can then be patterned and etched to form a plurality of via openings that are then filled with one or more sufficiently conductive materials, for example metals, metal silicides and/or metal nitrides, to form conductive vias 430. The conductive vias may be provided in a wide range of configurations and patterns that will provide sufficient conductive surface area (and corresponding current capacity) including, for example, the various patterns illustrated in the accompanying figures and discussed elsewhere in the specification.

The second interlayer dielectric layer 450 can also be patterned and etched to form a larger and more shallow opening above the conductive vias 430. A layer of a second or upper conductive material, typically a metal or a metal alloy, can then be formed on the patterned second interdielectric layer 450 and the upper portion removed to form a second or upper conductive material pattern 440 that is in electrical contact with the first or lower conductive material pattern 410 through the conductive vias 430. A protective pattern 460, such as a nitride pattern, can then be formed on the exposed surface portions of the second interdielectric layer 450 and overlap peripherial portions of the second conductive metal pattern 440 in order to reduce the risk of mechanical damage and/or contamination. As will be appreciated both those skilled in the art, additional conductive material patterns (not shown) may be incorporated into the interlayer dielectric layers 400, 450 for connecting the bonding pad structure(s) to other device circuitry.

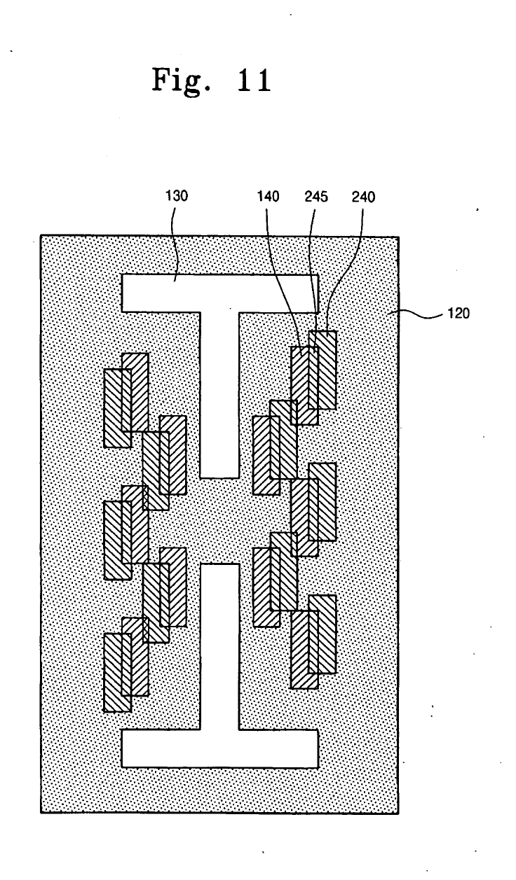

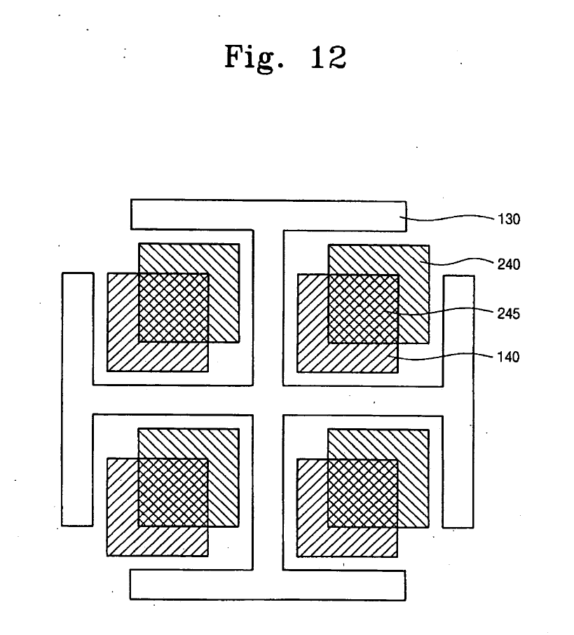

As illustrated in FIG. 11, the conductive via patterns 140, 240 arranged above and below a conductive pad 120 in which openings 130 are provided and filled with a dielectric material may be offset from one another to provide some area of vertical overlap. As illustrated in FIG. 11, the offset between the two patterns may be along a single axis, but radial and more complex offset configurations (not shown) may be utilized. As illustrated in FIG. 12, the opening 130 may be complex and serve to define separated regions on the conductive pad 120 with which corresponding via structures 140, 240 will be aligned. Again, as illustrated in FIG. 11, in FIG. 12 the two via patterns 140, 240 are offset from one another to reduce the size of the vertical overlap region 245, but are offset in more than one direction.

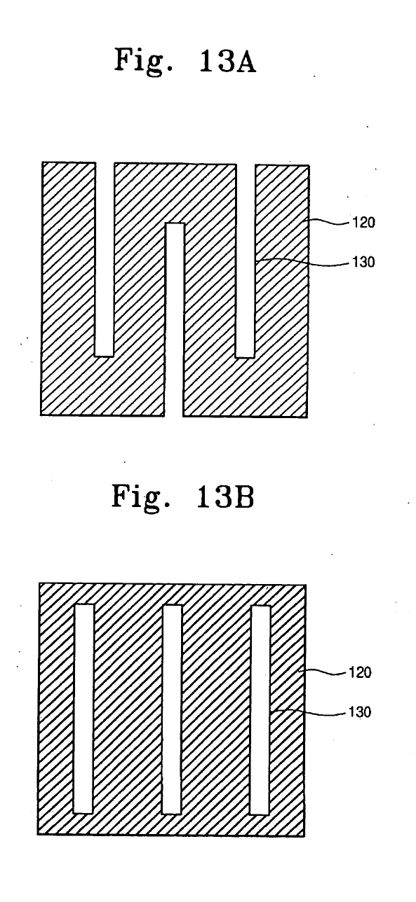

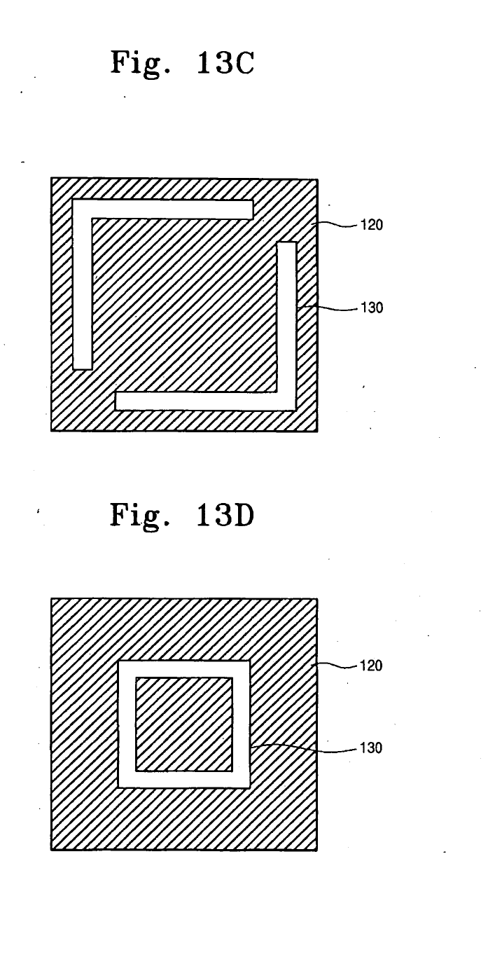

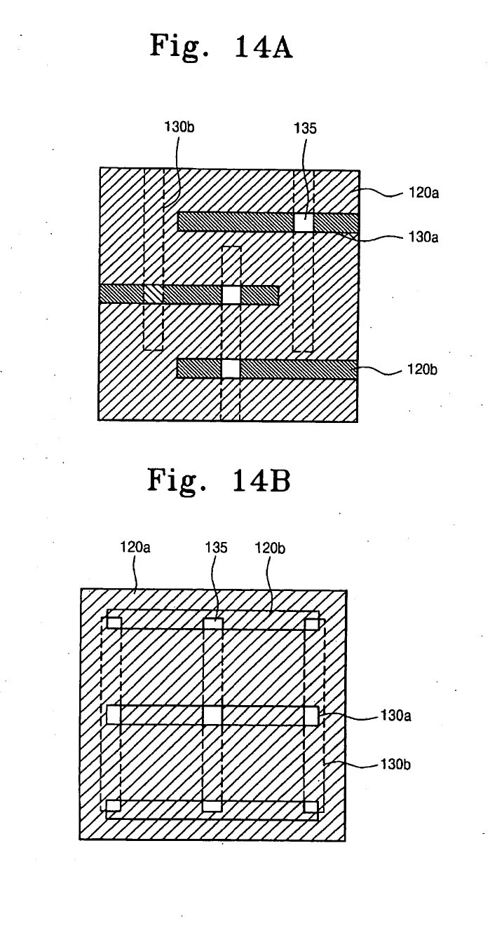

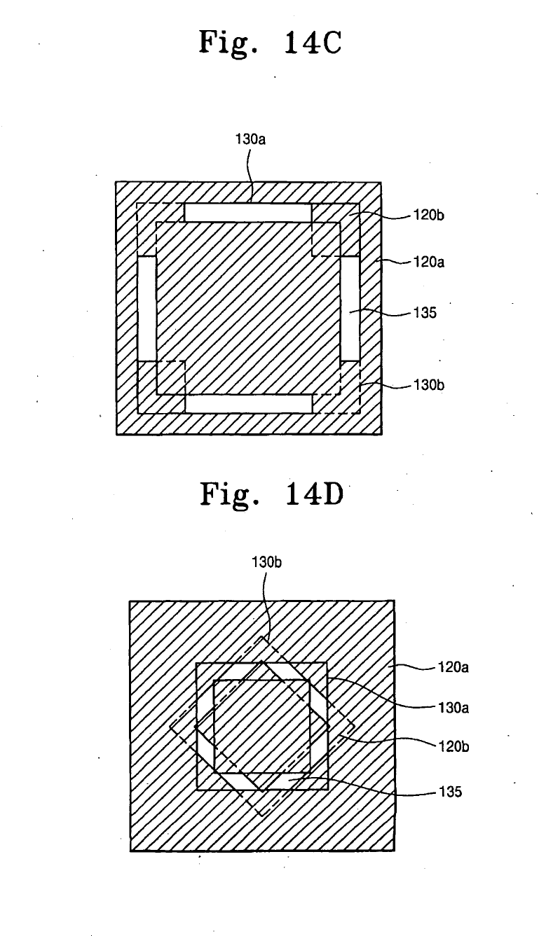

FIGS. 13A-13D illustrate various conductive patterns 120 in which are provided one or more slots and/or openings 130 that will allow a dielectric material to be intergrated into the bonding pad structure in a manner than may, for example, improve the processability and/or reliability of the resulting structure. FIGS. 14A-14B illustrate the overlapping regions resulting from a simple rotation (90° in the case of FIGS. 14A-14C and 45° in the case the FIG. 14D) of two identical patterns 120a, 120b having corresponding openings 130a, 130b. As illustrated in FIGS. 14A-14D, the regions in which the openings overlap 135 can be defined to provide a desired degree of vertical overlap between the corresponding dielectric and/or via structures.

As will be appreciated by those skilled in the art, the metal pads may be fabricated using a number of processes known and adapted for different materials. When copper is used as the primary conductor, for example, a dual damascene process can be used to form the metal pad(s) and via(s). A barrier layer (not shown) may be formed in the pad openings and/or via openings using, for example, Ta, TaN or combination thereof, prior to deposition of the copper layer. Conversely, if aluminum and/or aluminum alloys, for example aluminum and silicon, are used as the primary conductors, the vias may be filled with aluminum or another metal, such as tungsten.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

We claim:

1. A bonding pad structure comprising:
a first dielectric layer;
a first conductive pad pattern formed in the first dielectric layer and surrounding an elongated portion of the first dielectric layer;
a second dielectric layer formed on the first conductive pad pattern;
a first plurality of conductive vias having a first configuration formed through the second dielectric layer and in electrical contact with the first conductive pad pattern;
a second conductive pad pattern formed in the second dielectric layer in electrical contact with the first plurality of conductive vias and surrounding an elongated portion of the second dielectric layer;
a third dielectric layer formed on the second conductive pad pattern;
a second plurality of conductive vias having a second configuration formed through the third dielectric layer and in electrical contact with the second conductive pad pattern; and
a third conductive pad pattern formed in the third dielectric layer and in electrical contact with the second plurality of conductive vias.

2. The bonding pad structure according to claim 1, wherein:
the first configuration and the second configuration are substantially identical.

3. The bonding pad structure according to claim 1, wherein:
the first conductive pad pattern surrounds a plurality of elongated portions of the first dielectric layer; and
the second conductive pad pattern surrounds a plurality of elongated portions of the second dielectric layer.

4. The bonding pad structure according to claim 1, wherein:
the elongated portion of the first dielectric layer has an open configuration; and
the elongated portion of the second dielectric layer has an open configuration.

5. The bonding pad structure according to claim 1, wherein:
the elongated portion of the first dielectric layer represents no more than 15% of an area defined by the periphery of the first conductive pad structure.
the elongated portion of the second dielectric layer represents no more than 15% of an area defined by the periphery of the second conductive pad structure.

6. The bonding pad structure according to claim 1, wherein:
the elongated portion of the first dielectric layer is arranged to have a substantially perpendicular orientation relative to the elongated portion of the second dielectric layer.

7. The bonding pad structure according to claim 1, wherein:
the elongated portion of the first dielectric layer is arranged to have a substantially parallel and laterally offset orientation relative to the elongated portion of the second dielectric layer.

8. The bonding pad structure according to claim 1, wherein:
the first plurality of conductive vias are arranged in a laterally offset orientation to the second plurality of conductive vias.

9. The bonding pad structure according to claim 8, wherein:
the first plurality of conductive vias are arranged in a laterally offset orientation to the second plurality of conductive vias to provide a vertical overlap of less than 90%.

10. The bonding pad structure according to claim 8, wherein:
the first plurality of conductive vias are arranged in a laterally offset orientation to the second plurality of conductive vias to provide a vertical overlap of less than 50%.

11. The bonding pad structure according to claim 8, wherein:
the first plurality of conductive vias are arranged in a laterally offset orientation to the second plurality of conductive vias to provide a vertical overlap of less than 10%.

12. The bonding pad structure according to claim 3, wherein:
the first plurality of conductive vias are arranged to contact the first conductive pad pattern in regions between adjacent ones of the elongated portions of the first dielectric layer; and
the second plurality of conductive vias are arranged to contact the second conductive pad pattern in regions between adjacent ones of the elongated portions of the second dielectric layer.

13. The bonding pad structure according to claim 12, wherein:
the first plurality of conductive vias are arranged in a mesh pattern; and
the second plurality of conductive vias are arranged in the mesh pattern and contact the second conductive pad pattern in regions between adjacent ones of the elongated portions of the second dielectric layer.

14. A bonding pad structure comprising:
a first dielectric layer;
a first conductive pad pattern formed in the first dielectric layer and surrounding an elongated portion of the first dielectric layer;
a second dielectric layer formed on the first conductive pad pattern;
a first plurality of conductive vias having a first configuration formed through the second dielectric layer and in electrical contact with the first conductive pad pattern;
a second conductive pad pattern formed in the second dielectric layer in electrical contact with the first plurality of conductive vias; and
a passivation pattern formed on and exposing the majority of an upper surface of the second conductive pad pattern.

15. The bonding pad structure according to claim 14, wherein:
the first conductive pad pattern surrounds a plurality of elongated portions of the first dielectric layer.

16. The bonding pad structure according to claim 14, wherein:
the elongated portion of the first dielectric layer has an open configuration.

17. The bonding pad structure according to claim 15, wherein:
the elongated portions of the first dielectric layer have an open configuration.

18. The bonding pad structure according to claim 14, wherein:
the elongated portion of the first dielectric layer represents no more than 15% of an area defined by the periphery of the first conductive pad structure.

19. The bonding pad structure according to claim 15, wherein:
the elongated portions of the first dielectric layer represent no more than 15% of an area defined by the periphery of the first conductive pad structure.

20. A method of forming a bonding pad structure comprising:
forming a first dielectric layer;
removing portions of the first dielectric layer to form a first recessed conductive pad region surrounding an elongated portion of the first dielectric layer;
depositing a first conductive material layer;
removing an upper portion of the first conductive material layer to form a first conductive pad surrounding the elongated portion of the first dielectric layer;
forming a second dielectric layer;
removing first portions of the second dielectric layer to form a first plurality of via openings having a first configuration;
removing a second portion of the second dielectric layer to form a second recessed conductive pad region surrounding an elongated portion of the second dielectric layer;
depositing a second conductive material layer;
removing an upper portion of the second conductive material layer to form a second conductive pad surrounding the elongated portion of the second dielectric layer and a first plurality of conductive vias establishing electrical contact between the first and second conductive pads;
forming a third dielectric layer;
removing first portions of the third dielectric layer to form a second plurality of via openings;
removing a second portion of the third dielectric layer to form a third recessed conductive pad region;
depositing a third conductive material layer; and
removing an upper portion of the third conductive material layer to form a third conductive pad and a second plurality of conductive vias establishing electrical contact between the second and third conductive pads.

21. The method of forming a bonding pad structure according to claim 20, wherein:
the second plurality of conductive vias are arranged in the first configuration and offset in a lateral direction from the first plurality of conductive vias.

22. The method of forming a bonding pad structure according to claim 20, wherein:
the elongated portion of the first dielectric layer is rotationally offset from the elongated portion of the second dielectric layer.

23. A method of forming a bonding pad structure comprising, in sequence:
forming a first dielectric layer;
forming a first conductive material layer;
removing portions of the first conductive material layer to form a first conductive material pattern, the pattern having an elongated opening through which a portion of a surface of the first dielectric layer is exposed;
depositing a second dielectric layer;
removing an upper portion of the second dielectric layer to expose a surface of the first conductive material pattern and form a first conductive pad surrounding the elongated opening and an elongated portion of the second dielectric layer;
forming a third dielectric layer;
removing first portions of the third dielectric layer to form a first plurality of via openings having a first configuration;
forming a second conductive material layer;
removing a first portion of the second conductive material layer to form a first plurality of conductive vias in electrical contact with the first conductive pad; and
forming a third conductive material layer in electrical contact with the first plurality of conductive vias.

24. The method of forming a bonding pad structure according to claim 23, further comprising, in sequence:
removing first portions of the third conductive material layer to form a second conductive material pattern, the pattern having an elongated opening through which a portion of a surface of the third dielectric layer is exposed;
forming a fourth dielectric layer;
removing an upper portion of the fourth dielectric layer to expose a surface of the second conductive material pattern and form a second conductive pad surrounding the elongated opening and an elongated portion of the fourth dielectric layer.
